(19) United States
(12) Patent Application Publication
(10) Pub. No.: US 2021/0392742 A1
(43) Pub. Date: Dec. 16, 2021

(54) EMBEDDED MICROSTRIP WITH OPEN SLOT FOR HIGH SPEED SIGNAL TRACES

(71) Applicant: Innogrit Technologies Co., Ltd., Shanghai (CN)

(72) Inventors: Shiann-Ming LIOU, Campbell, CA (US); Yanwen BAI, Shanghai (CN)

(21) Appl. No.: 16/898,503

(22) Filed: Jun. 11, 2020

(51) Int. Cl. H05K 1/02

(52) U.S. Cl. CPC H05K 1/0245; H05K 2201/09236; H05K 1/0253; H05K 1/024

(57) ABSTRACT

Apparatus and methods are provided for providing provide high-speed traces in inner layers of semiconductor packages or PCBs. In an exemplary embodiment, there is provided an circuit assembly that may comprise a first ground reference plane, a second ground reference plane and a dielectric layer between the first ground reference plane and the second ground reference plane. The dielectric layer may comprise a pair of traces embedded therein and the first ground reference plane may have an opening corresponding to the pair of traces. The opening may have a width equal to or larger than a width of the pair of traces, which may be equal to widths of respective traces of the pair of traces and a gap between the pair of traces.

### TECHNICAL FIELD

The disclosure herein relates to high speed connection, particularly relates to high speed signal traces routed on inner layers of a semiconductor package or a printed circuit board (PCB).

### BACKGROUND

Planar transmission lines, sometimes referred to as traces, have been used to interconnect components on printed circuits and integrated circuits for a long time. Typical types of planar transmission lines include microstrip and stripline. Microstrip is a surface structure not suitable for internal layers of integrated IC packages or printed circuit boards (PCBs) so stripline is generally used for internal layers. Signal speeds are getting faster in modern electronic circuits and high-speed signal traces have a high requirement for impedance control. Because the normal form of stripline has a high trace capacitance, it is hard to achieve targeted impedance for traces routed on inner layers of integrated IC packages or PCBs as stripline structure. Moreover, the required impedance may be achieved by reducing trace width or spacing out traces but some time the limitation of process capability makes this approach costly or hard to achieve. One other method is to increase the dielectric layers thickness to increase the distance between reference planes and traces, but this will increase the substrate or PCB thickness and make the IC package or PCB hard to meet height requirements.

### SUMMARY

A continuing need exists for improved high-speed signal traces on internal layers of integrated IC packages or PCBs. The disclosed subject matter relates to circuit assemblies and methods that provide reduced the capacitance to improve the chance of hitting the targeted impedance by a low-cost approach. In various embodiment, a signal layer may be located in dielectric material between two ground reference planes, and the metal area(s) on one of the two ground reference planes opposing to the traces may be removed to form an embedded microstrip structure.

In an exemplary embodiment, there is provided a circuit assembly. The circuit assembly may comprise a first ground reference plane, a second ground reference plane and a dielectric layer between the first ground reference plane and the second ground reference plane. The dielectric layer may comprise a trace embedded therein and the first ground reference plane may have an opening corresponding to the trace. The opening may have a width equal to or larger than a width of the trace.

In another exemplary embodiment, there is provided a circuit assembly. The circuit assembly may comprise a first ground reference plane, a second ground reference plane and a dielectric layer between the first ground reference plane and the second ground reference plane. The dielectric layer may comprise a pair of traces embedded therein and the first ground reference plane may have an opening corresponding to the pair of traces. The opening may have a width equal to or larger than a width of the pair of traces, which may be equal to widths of respective traces of the pair of traces and a gap between the pair of traces.

In yet another exemplary embodiment, there is provide a method for making a circuit assembly. The method may comprise forming a first conductive plane with an opening, forming a dielectric layer on the first conductive plane with a pair of traces corresponding to the opening embedded in the dielectric layer and forming a second conductive plane to sandwich the dielectric layer with the first conductive plane. The opening may have a width equal to or larger than a width of the pair of traces, which may be equal to widths of respective traces of the pair of traces and a gap between the pair of traces.

### BRIEF DESCRIPTION OF FIGURES

FIG. 1A schematically shows a cross-sectional view of a circuit assembly in accordance with an embodiment of the present disclosure.

FIG. 1B schematically shows a portion of the circuit assembly in accordance with an embodiment of the present disclosure.

FIG. 2A schematically shows a cross-sectional view of a circuit assembly in accordance with another embodiment of the present disclosure.

FIG. 2B schematically shows a portion of the circuit assembly in accordance with another embodiment of the present disclosure.

FIG. 3 schematically shows a cross-sectional view of a multi-layer circuit assembly in accordance with an embodiment of the present disclosure.

FIG. 4 schematically shows a cross-sectional view of a multi-layer circuit assembly in accordance with another embodiment of the present disclosure.

FIG. 5 schematically shows a cross-sectional view of a multi-layer circuit assembly in accordance with yet another embodiment of the present disclosure.

FIG. 6 is a flowchart of a process for making a circuit assembly in accordance with an embodiment of the present disclosure.

### DETAILED DESCRIPTION

Specific embodiments according to the present disclosure will now be described in detail with reference to the accompanying figures. Like elements in the various figures are denoted by like reference numerals for consistency.

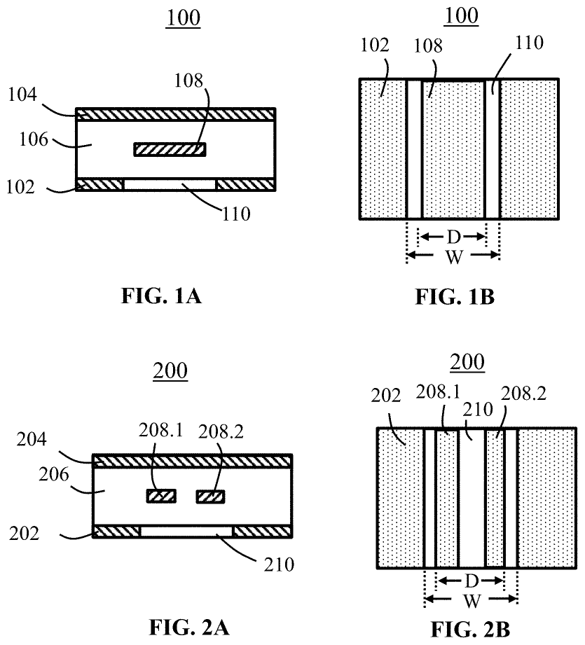

FIG. 1A schematically shows a cross-sectional view of a circuit assembly 100 in accordance with an embodiment of the present disclosure. The circuit assembly 100 may comprise a first ground reference plane 102, a second ground reference plane 104 and a dielectric layer 106 between the first ground reference plane 102 and the second ground reference plane 104. It should be noted that a ground reference plane may also be referred to as a ground plane or a reference plane in some embodiments, and they may be shorted by electrical connections using vias through dielectric layer 106. The dielectric layer 106 may have a trace 108 embedded therein. The first ground reference plane 102 may have an opening 110. In some embodiments, the trace 108 and the corresponding opening 110 may form a structure referred to as an open slot embedded microstrip structure. FIG. 1B schematically shows another view of the circuit assembly 100. The opening 110 may have an elongated shape and run longitudinally parallel to the trace 108 as shown in FIG. 1B. The opening 110 may be a slot formed on the ground reference plane 102 by cutting off a portion of the ground reference plane 102 covering to a footprint of the trace 108 projected on the ground reference plane 102. As shown in FIG. 1B, the trace 108 may have a width D and the opening 110 may have a width W. In various embodiments, the width W of the opening 110 may be equal to or larger than the width D of the trace 108.

The first ground reference plane 102, the second ground reference plane 104 and the trace 108 may be made using same or different conductive materials, such as, but not limited to, copper. The dielectric layer 106 may be filled with a non-conductive dielectric material, such as, but not limited to, a prepreg material. The opening 110 may be filled with the same dielectric material as the dielectric layer 106 or a different non-conductive dielectric material.

In some embodiments, the circuit assembly 100 may be an integrated circuit (IC) package, and the first ground reference plane 102, the second ground reference plane 104 and the dielectric layer 106 with the embedded trace 108 may be part of a package substrate. In some other embodiments, the circuit assembly 100 may be a printed circuit board (PCB), and the first ground reference plane 102, the second ground reference plane 104 and the dielectric layer 106 may be part of PCB layers and the embedded trace 108 may be one of many traces of the PCB.

It should be noted that the circuit assembly 100 may have other layers in some embodiments. For example, there may be one or more layers on top of the ground reference plane 104, one or more layers underneath the ground reference plane 102, or one or more layers both on top of the ground reference plane 104 and underneath the ground reference plane 102. In some embodiments, the dielectric layer 106 may include two or more layers of different dielectric materials.

FIG. 2A schematically shows a cross-sectional view of a circuit assembly 200 in accordance with an embodiment of the present disclosure. The circuit assembly 200 may comprise a first ground reference plane 202, a second ground reference plane 204 and a dielectric layer 206 between the first ground reference plane 202 and the second ground reference plane 204. The dielectric layer 206 may have a pair of traces 208.1 and 208.2 embedded therein. In one embodiment, the pair of traces 208.1 and 208.2 may be a differential pair of high speed signal lines. The circuit assembly 200 may be an embodiment of the circuit assembly 100 in which a trace 108 is replaced with a differential pair of signal transmission lines.

The first ground reference plane 202 may have an opening 210. In some embodiments, the traces 208.1 and 208.2 and the corresponding opening 210 may also form an embodiment of an open slot embedded microstrip structure. FIG. 2B schematically shows another view of the circuit assembly 200. The opening 210 may have an elongated shape and run longitudinally parallel to the traces 208.1 and 208.2 as shown in FIG. 2B. The opening 210 may be a slot formed on the ground reference plane 202 by cutting off a portion of the ground reference plane 202 corresponding to a footprint of the traces 208.1 and 208.2 projected on the ground reference plane 202. As shown in FIG. 2B, the traces 208.1 and 208.2 may have a projected width D on the ground reference plane 202 and the opening 210 may have a width W. In various embodiments, the width W of the opening 210 may be equal to or larger than the width D of the traces 208.1 and 208.2.

The first ground reference plane 202, the second ground reference plane 204 and the traces 208.1 and 208.2 may be made using same or different conductive materials, such as, but not limited to, copper. The dielectric layer 206 may be filled with a non-conductive dielectric material, such as, but not limited to, a prepreg material. The opening 210 may be filled with the same dielectric material as the dielectric layer 206 or a different non-conductive dielectric material.

In some embodiments, the circuit assembly 200 may be an integrated circuit (IC) package, and the first ground reference plane 202, the second ground reference plane 204 and the dielectric layer 206 with the embedded traces 208.1 and 208.2 may be part of a package substrate. In some other embodiments, the circuit assembly 200 may be a printed circuit board (PCB), and the first ground reference plane 202, the second ground reference plane 204 and the dielectric layer 206 may be part of PCB layers and the embedded traces 208.1 and 208.2 may be two of many traces of the PCB.

It should be noted that the circuit assembly 200 may have other layers in various embodiments. For example, there may be one or more layers on top of the ground reference plane 204, one or more layers underneath the ground reference plane 202, or one or more layers both on top of the ground reference plane 204 and underneath the ground reference plane 202. In some embodiments, the dielectric layer 206 may include two or more layers of different dielectric materials.

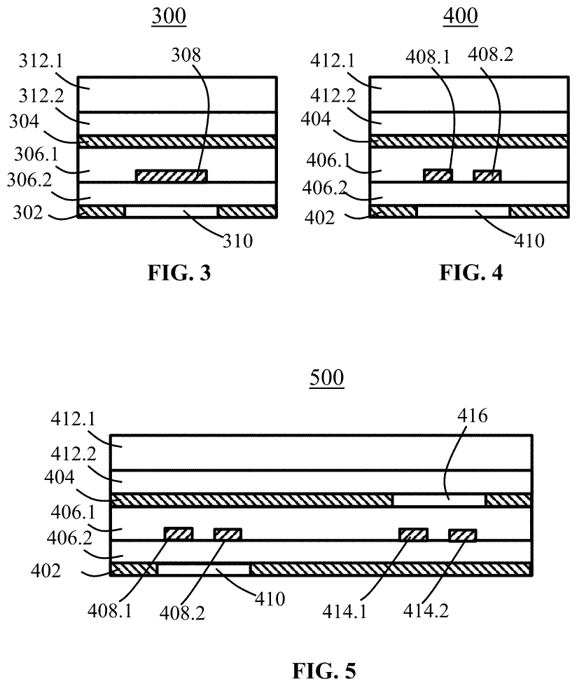

FIG. 3 schematically shows a cross-sectional view of a multi-layer circuit assembly 300 in accordance with an embodiment of the present disclosure. The multi-layer circuit assembly 300 may be another embodiment of the circuit assembly 100 with more layers. The circuit assembly 300 may comprise a first ground reference plane 302, a second ground reference plane 304 and a plurality of dielectric layers 306.1 and 306.2 between the first ground reference plane 302 and the second ground reference plane 304. A trace 308 may be embedded in the dielectric layer 306.1 and on top of the dielectric layer 306.2. In addition, the circuit assembly 300 may further comprise a plurality of dielectric layers 312.1 and 312.2 on top of the second ground reference plane 304.

The first ground reference plane 302 may have an opening 310. The opening 310 may have an elongated shape and run longitudinally parallel to the trace 308. The opening 310 may be a slot formed on the ground reference plane 302 by cutting off a portion of the ground reference plane 302 corresponding to a footprint of the trace 308 projected on the ground reference plane 302. The trace 308 may have a width D and the opening 210 may have a width W. In various embodiments, the width of the opening 310 may be equal to or larger than the width of the trace 308.

The first ground reference plane 302, the second ground reference plane 304 and the trace 308 may be made using same or different conductive materials, such as, but not limited to, copper. The dielectric layers 306.1, 306.2, 312.1 and 312.2 may be filled with the same or different non-conductive dielectric materials, such as, but not limited to, a prepreg material. The opening 310 may be filled with the same dielectric material as the dielectric layer 306.2 or a different non-conductive dielectric material.

In some embodiments, the circuit assembly 300 may be an integrated circuit (IC) package, and the first ground reference plane 302, the second ground reference plane 304, the dielectric layers 306.1 and 306.2 with the embedded trace 308 and the dielectric layers 312.1 and 312.2 may be part of a package substrate. In some other embodiments, the circuit assembly 300 may be a printed circuit board (PCB), and the first ground reference plane 302, the second ground reference plane 304 and the dielectric layers 306.1, 306.2, 312.1 and 312.2 may be part of PCB layers and the embedded trace 308 may be one of many traces of the PCB.

It should be noted that the circuit assembly 300 may have other layers in various embodiments. For example, there may be one or more layers on top of the dielectric layer 312.1, one or more layers underneath the ground reference plane 302, or one or more layers both on top of the dielectric layer 312.1 and underneath the ground reference plane 302.

FIG. 4 schematically shows a cross-sectional view of a multi-layer circuit assembly 400 in accordance with another embodiment of the present disclosure. The circuit assembly 400 may be an embodiment of the circuit assembly 300 in which the signal transmission line 308 may be replaced by a pair of signal transmission lines 408.1 and 408.2. In one embodiment, the pair of signal transmission lines 408.1 and 408.2 may be a differential pair of signal transmission lines. Other components of circuit assembly 400 may correspond to the other components of circuit assembly 300 and may be identical to their counter-parts of circuit assembly 300. For example, the circuit assembly 400 may comprise the ground reference planes 402 and 404 that may correspond to the ground reference planes 302 and 304 of circuit assembly 300. Moreover, the circuit assembly 400 may comprise the dielectric layers 406.1, 406.2, 412.1 and 412.2 that may correspond to the dielectric layers 306.1, 306.2, 312.1 and 312.2 of circuit assembly 300. In addition, the opening 410 may correspond to the opening 310 of circuit assembly 300 and the width of the opening 410 may be equal to or larger than the width of the pair of transmission lines 408.1 and 408.2 (e.g., the combined widths of the two traces plus the gap between the two traces).

FIG. 5 schematically shows a cross-sectional view of a multi-layer circuit assembly 500 in accordance with yet another embodiment of the present disclosure. A circuit assembly according to an embodiment of the present disclosure may comprise more than one transmission line or more than one pair of transmission lines that have accompanying openings in a ground reference plane. The circuit assembly 500 may be an embodiment of the circuit assembly 400 that shows two pairs of signal transmission lines that each pair of signal transmission lines have their own accompanying opening in a ground reference plane. As shown in FIG. 5, in addition to the signal transmission lines 408.1 and 408.2, circuit assembly 500 may comprise another pair of signal transmission lines 414.1 and 414.2. In one embodiment, the pair of signal transmission lines 414.1 and 414.2 may also be a differential pair of signal transmission lines.

It should be noted that an opening corresponding to a signal transmission line (or a pair of signal transmission lines) may be on either of the two ground reference planes sandwiching the dielectric layer in which the signal transmission line (or the pair of signal transmission lines) may be embedded therein. That is, in an embodiment of an open slot embedded microstrip structure, the opening may be in either one of the two ground reference planes sandwiching the dielectric layer in which the signal transmission line may be embedded therein. As an example, FIG. 5 shows that the opening 416 for the pair of signal transmission lines 414.1 and 414.2 may be a slot on the ground reference plane 404 (e.g., above the pair of signal transmission lines 414.1 and 414.2).

In some embodiments, where there may be a plurality of open slot embedded microstrip structures, these multiple openings and their corresponding traces may be placed with their respective longitudinal directions according to design requirements. For example, the opening 416 (and pair of signal transmission lines 414.1 and 414.2) may have an elongated shape and run longitudinally parallel to the opening 410 (and pair of signal transmission lines 408.1 and 408.2) in FIG. 5, although FIG. 5 merely shows the cross-section of them. But in another embodiment, the opening 416 (and pair of signal transmission lines 414.1 and 414.2) may be longitudinally orthogonal or slanted in another angle (e.g., 30 degrees, 45 degrees, 60 degrees, etc.) relative to the opening 410 (and pair of signal transmission lines 408.1 and 408.2).

Moreover, in some embodiments, where there may be a plurality of open slot embedded microstrip structures, these traces or pairs of traces may be placed in different signal layers. For example, the pair of signal transmission lines 414.1 and 414.2 may be placed in a same signal layer as the pair of signal transmission lines 408.1 and 408.2 in FIG. 5, but in another embodiment, the pair of signal transmission lines 414.1 and 414.2 may be placed in a signal layer different from the signal layer where the pair of signal transmission lines 408.1 and 408.2 may be placed. It should be noticed that regardless which signal layer a trace or a pair of traces may be placed, the trace or the pair of traces may have a corresponding opening in an adjacent ground reference plane (e.g., one of the two ground reference planes sandwiching the dielectric layer where the signal layer is embedded therein). And the corresponding opening may have a width equal to or larger than the width of the trace or the width of the pair of traces.

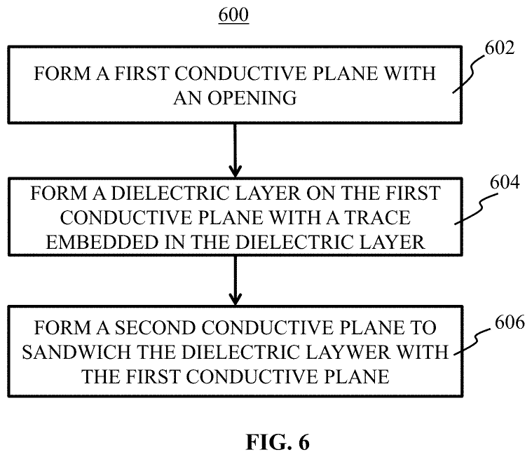

FIG. 6 is a flowchart of a process 600 for making a circuit assembly in accordance with an embodiment of the present disclosure. The process 600 may be followed to make an exemplary circuit assembly (e.g., 100, 200, 300, 400 or 500). At block 602, a first conductive plane may be formed with an opening. For example, the first ground plane 102 may be formed for the circuit assembly 100 and the first ground plane 102 may have the opening 110. In some embodiments, the opening may be one of many openings and have an elongated shape, and may be formed using for example, chemical etching or mechanical grinding, or any known or yet to be developed technique. At block 604, a dielectric layer may be formed on the first conductive plane with a trace embedded in the dielectric layer. In some embodiments, the trace may be one of a pair of traces and part of a signal layer embedded in the dielectric layer. As described herein, for example, with respect to FIGS. 3, 4 and 5, the dielectric layer may comprise more than one layer of dielectric material. In these embodiments, a first dielectric layer may be formed to cover the first conductive plane and the opening on the first conductive plane. Then a signal layer including the trace may be formed on the first dielectric layer. In different embodiment, the signal layer may comprise one or many pairs of traces. A pair of traces may be, for example, a differential pair of signal transmission lines. And then a second dielectric layer may be formed over the signal layer and the first dielectric layer to embed the signal layer. At block 606, a second conductive plane may be formed to sandwich the dielectric layer with the first conductive plane. In some embodiments, the first and second conductive planes may be shorted by one or more electrical vias through the dialectical layer. Moreover, in some embodiments, each pair of traces may have a corresponding opening formed in the first conductive plane or the second conductive plane.

It should be noted that in some embodiments, the ground reference planes and openings may be formed using known and yet to be developed techniques for forming conductive patterns that may be insulated from other parts of a circuit assembly, which may be an IC package or a PCB. The ground reference planes may be formed using same or different conductive material, such as, but not limited to, copper or gold.

One exemplary embodiment according to the present disclosure may provide a circuit assembly that may comprise a first ground reference plane, a second ground reference plane and a dielectric layer between the first ground reference plane and the second ground reference plane. The dielectric layer may comprise a trace embedded therein and the first ground reference plane may have an opening corresponding to the trace. The opening may have a width equal to or larger than a width of the trace.

In one embodiment, the trace may be one of a pair of signal transmission lines and the opening may have a width equal to or larger than a width of the pair of signal transmission lines. The width of the pair of signal transmission lines may be equal to widths of respective signal lines of the pair of signal transmission lines and a gap between the pair of signal transmission lines.

In one embodiment, the pair of signal transmission lines may be a differential pair of signal transmission lines.

In one embodiment, the opening may have an elongated shape and run longitudinally parallel to the pair of signal transmission lines, and may be filled with a dielectric material.

In one embodiment, the trace may be part of a signal layer in a printed circuit board.

In one embodiment, the trace may be part of a signal layer in an integrated circuit package.

In one embodiment, the circuit assembly may further comprise at least another dielectric layer on a side of first ground reference plane opposite the dielectric layer, at least another dielectric layer on a side of second ground reference plane opposite the dielectric layer, or both.

Another exemplary embodiment according to the present disclosure may provide a circuit assembly that may comprise a first ground reference plane, a second ground reference plane and a dielectric layer between the first ground reference plane and the second ground reference plane. The dielectric layer may comprise a pair of traces embedded therein and the first ground reference plane may have an opening corresponding to the pair of traces. The opening may have a width equal to or larger than a width of the pair of traces, which may be equal to widths of respective traces of the pair of traces and a gap between the pair of traces.

In one embodiment, the pair of traces may be a differential pair of traces.

In one embodiment, the pair of traces may be part of a signal layer that may have a plurality of pairs of traces, and each pair of the plurality of pairs of traces may have a corresponding opening on the first ground reference plane or the second reference plane.

In one embodiment, the opening may have an elongated shape and run longitudinally parallel to the pair of traces, and may be filled with a dielectric material.

In one embodiment, the trace may be part of a signal layer in a printed circuit board.

In one embodiment, the trace may be part of a signal layer in an integrated circuit package.

In one embodiment, the circuit assembly may further comprise at least another dielectric layer on a side of first ground reference plane opposite the dielectric layer, at least another dielectric layer on a side of second ground reference plane opposite the dielectric layer, or both.

In yet another exemplary embodiment, there is provide a method for making a circuit assembly. The method may comprise forming a first conductive plane with an opening, forming a dielectric layer on the first conductive plane with a pair of traces corresponding to the opening embedded in the dielectric layer and forming a second conductive plane to sandwich the dielectric layer with the first conductive plane. The opening may have a width equal to or larger than a width of the pair of traces, which may be equal to widths of respective traces of the pair of traces and a gap between the pair of traces.

In one embodiment, the pair of traces may be a differential pair of traces.

In one embodiment, forming the dielectric layer may further comprise forming a first dielectric layer on the first conductive plane to cover the first conductive plane and the opening, forming a signal layer over the first dielectric layer and forming a second dielectric layer over the first dielectric layer and the signal layer to embed the signal layer in the second dielectric layer. The signal layer may have the pair of traces formed thereon.

In one embodiment, the opening may have an elongated shape and run longitudinally parallel to the pair of traces, and may be filled with a dielectric material.

In one embodiment, the trace may be part of a signal layer in a printed circuit board.

In one embodiment, the trace may be part of a signal layer in an integrated circuit package.

Various operations may be described as multiple discrete operations in turn, in a manner that may be helpful in understanding embodiments of the present invention; however, the order of description should not be construed to imply that these operations are order dependent. Moreover, some embodiments may include more or fewer operations than may be described.

The description may use the phrases “in an embodiment,” “in embodiments,” “in some embodiments,” or “in various embodiments,” which may each refer to one or more of the same or different embodiments. Furthermore, the terms “comprising,” “including,” “having,” and the like, as used with respect to embodiments of the present invention, are synonymous.

The terms “coupled to,” along with its derivatives, may be used herein. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled to each other.

The terms chip, die, integrated circuit, monolithic device, semiconductor device, and microelectronic device are often used interchangeably in the microelectronics field. The present invention is applicable to all of the above as they are generally understood in the field.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A circuit assembly, comprising:
a first ground reference plane;
a second ground reference plane;
a dielectric layer between the first ground reference plane and the second ground reference plane, the dielectric layer comprising a trace consisting of a single layer and having a single width embedded therein and the first ground reference plane having an opening corresponding to the trace, wherein the opening has a width equal to or larger than the single width of the trace.

2. The circuit assembly of claim 1, wherein the trace is one of a pair of signal transmission lines and the opening has a width equal to or larger than a width of the pair of signal transmission lines, wherein the width of the pair of signal transmission lines is equal to widths of respective signal lines of the pair of signal transmission lines and a gap between the pair of signal transmission lines.

3. The circuit assembly of claim 2, wherein the pair of signal transmission lines are a differential pair of signal transmission lines.

4. The circuit assembly of claim 2, wherein the opening has an elongated shape and run longitudinally parallel to the pair of signal transmission lines, and is filled with a dielectric material.

5. The circuit assembly of claim 1, wherein the trace is part of a signal layer in a printed circuit board.

6. The circuit assembly of claim 1, wherein the trace is part of a signal layer in an integrated circuit package.

7. The circuit assembly of claim 1, further comprising at least another dielectric layer on a side of first ground reference plane opposite the dielectric layer, at least another dielectric layer on a side of second ground reference plane opposite the dielectric layer, or both.

8. A circuit assembly, comprising:
a first ground reference plane;
a second ground reference plane;
a dielectric layer between the first ground reference plane and the second ground reference plane, the dielectric layer comprising a pair of traces each consisting of a single layer and having a respective single width embedded therein and the first ground reference plane having an opening corresponding to the pair of traces, wherein the opening has a width equal to or larger than a width of the pair of traces, the width of the pair of traces is equal to the single widths of the pair of traces and a gap between the pair of traces.

9. The circuit assembly of claim 8, wherein the pair of traces are a differential pair of traces.

10. The circuit assembly of claim 8, wherein the pair of traces are part of a signal layer that has a plurality of pairs of traces, and each pair of the plurality of pairs of traces have a corresponding opening on the first ground reference plane or the second reference plane.

11. The circuit assembly of claim 8, wherein the opening has an elongated shape and run longitudinally parallel to the pair of traces, and is filled with a dielectric material.

12. The circuit assembly of claim 8, wherein the pair of traces are part of a signal layer in a printed circuit board.

13. The circuit assembly of claim 8, wherein the pair of traces are part of a signal layer in an integrated circuit package.

14. The circuit assembly of claim 8, further comprising at least another dielectric layer on a side of first ground reference plane opposite the dielectric layer, at least another dielectric layer on a side of second ground reference plane opposite the dielectric layer, or both.

15-20. (canceled)

21. A circuit assembly, comprising:
a first ground reference plane having an elongated opening;
a second ground reference plane; and
a dielectric layer between the first ground reference plane and the second ground reference plane, the dielectric layer having a single trace embedded therein corresponding to the elongated opening in the first ground reference, wherein the single trace consists of a single layer and has a single width, and the elongated opening has a width equal to or larger than the single width of the single trace.
